(19) United States
(12) Patent Application Publication
(10) Pub. No.: US 2008/0283952 A1
(43) Pub. Date: Nov. 20, 2008

(54) Semiconductor Package, Method of Fabricating the Same and Semiconductor Package Module For Image Sensor

(76) Inventors: Hyun-Kyu Choi, Cheonan-City (KR); Chor Hong Koh, Singapore (SG)

Correspondence Address: IPLA P.A., 3580 WILSHIRE BLVD., 17TH FLOOR, LOS ANGELES, CA, 90010, US

(21) Appl. No.: 12/091,285

(22) PCT Filed: Dec. 22, 2006
(86) PCT No.: PCT/KR2006/005654

§ 371 Date: Apr. 23, 2008

(30) Foreign Application Priority Data
Dec. 24, 2005 (KR) 10-2005-0129182
Feb. 3, 2006 (KR) 10-2006-0010626
Aug. 18, 2006 (KR) 10-2006-0077933

(51) Int. Cl. H01L 23/28; H01L 23/48; H01L 27/00; H01L 21/00

(52) U.S. Cl. 257/433; 257/690; 438/123; 250/370.08; 257/E23.116

(57) ABSTRACT

Provided are a semiconductor package, a method of fabricating the same, and a semiconductor package module for an image sensor The semiconductor package includes a mounting portion on which a semiconductor chip is mounted; a semiconductor chip including a plurality of bonding pads disposed along an edge thereof, wherein the semiconductor chip adhered onto the mounting portion; a plurality of leads spaced apart from a sidewall of the semiconductor chip and having a greater height than the semiconductor chip; an encapsulant for fixing the mounting portion and the leads and encapsulating a bottom surface and a sidewall of the semiconductor package and exposing top and bottom surfaces of the leads; bonding wires for connecting the bonding pads of the semiconductor chip with the exposed top surfaces of the leads; and a transparent plate adhered onto the leads a predetermined space apart from the semiconductor chip.

### TECHNICAL FIELD

The present invention relates to a semiconductor package, and more particularly, to a semiconductor package including a semiconductor chip for an image sensor, a method of fabricating the same, and a semiconductor package module for an image sensor.

### BACKGROUND ART

A semiconductor package including a semiconductor chip for a CMOS image sensor (CIS), has been widely used in cameras for portable phones or charge coupled devices (CCDs) that have been rapidly developed in recent years. Owing to consumers' increased demands for high-performance light-weight simple configurations, many studies have been undertaken to develop a semiconductor package that can be used in a chip-size package (CSP) when mounting a semiconductor package on a printed circuit board (PCB).

Conventionally, a ceramic package and a plastic package have been used as CSPs for image sensors.

FIG. 1 is a cross sectional view of a conventional ceramic package for an image sensor.

Referring to FIG. 1, a semiconductor chip 12 is mounted on a package bottom portion 11a using an epoxy-based adhesive 16. The package bottom portion 11a is formed of a ceramic material. A plurality of bonding pads 12a are formed along an edge of a top surface of the semiconductor chip 12. A plurality of external leads 15 and a plurality of internal leads 17 are formed on the package bottom portion 11a. The external leads 15 function as contact portions that may be electrically connected to a specific circuit of a PCB (not shown), while the internal leads 17 function as contact portions that may be electrically connected to the bonding pads 12a through a plurality of bonding wires 13. A package wall portion 11b, which is formed of a ceramic material, is spaced apart from the semiconductor chip 12. A transparent plate 14, for example, a glass plate, is formed on the package wall portion 11b.

However, since the above-described ceramic package is structurally complicated, there is a specific limit in fabricating the ceramic package to be light and simple. Also, as ceramic materials are expensive, fabrication costs are further increased because the ceramic package is fabricated in single units.

FIG. 2 is a cross sectional view of a conventional plastic package for an image sensor.

Referring to FIG. 2, a semiconductor chip 22 is mounted on a central planar surface of an epoxy molding compound (EMC) encapsulant 21 with an external lead 25 using an adhesive 26. A plurality of bonding pads 22a are formed along an edge of a top surface of the semiconductor chip 22. The external lead 25 is formed through the encapsulant 21 to form an internal lead end portion 27 in an inner space of the package. The internal lead end portion 27 is electrically connected to the bonding pad 22a by a bonding wire 23. Meanwhile, a transparent plate 24, for example, a glass plate, is spaced apart from the semiconductor chip 22 and formed on of an inner wall of the encapsulant 21.

Like the ceramic package, the plastic package is also structurally complicated, so it is difficult to fabricate the plastic package to be sufficiently light and simple. Therefore, it is necessary to develop a semiconductor package for an image sensor, which is lighter and simpler than conventional semiconductor packages for an image sensor, can be fabricated in a simple process with reduced costs, and is suitable for mass production.

### DETAILED DESCRIPTION OF THE INVENTION

### Technical Problem

The present invention provides a semiconductor package that is light and simple and overcomes conventional problems.

Also, the present invention provides a method of fabricating the semiconductor package using a simplified process at low fabrication cost.

Further, the present invention provides a semiconductor package module for an image sensor that employs the semiconductor package.

### Technical Solution

According to an aspect of the present invention, there is provided a semiconductor package including a mounting portion on which a semiconductor chip is mounted, wherein the mounting portion supports the semiconductor chip. A semiconductor chip includes a plurality of bonding pads disposed along an edge thereof and is adhered onto the mounting portion. A plurality of leads are spaced apart from a sidewall of the semiconductor chip and have a greater height than the semiconductor chip. An encapsulant fixes the mounting portion and the leads, encapsulates a bottom surface and a sidewall of the semiconductor package, and exposes top and bottom surfaces of the leads. Bonding wires connect the bonding pads of the semiconductor chip with the exposed top surfaces of the leads.

Meanwhile, the semiconductor chip may further include a transparent plate that is adhered onto the leads a predetermined space apart from the semiconductor chip. The transparent plate may be replaced by an opaque plate, which is formed of a metal or a plastic. The predetermined space may be filled with a transparent material, for example, a transparent epoxy material, to encapsulate the semiconductor chip. When a transparent material is used, the transparent plate may or may not be formed.

The mounting portion may be integrally formed with the encapsulant using the same material, for example, epoxy molding compound (EMC). The mounting portion may be a lead frame pad, which is formed of the same material as the leads and separated from the leads.

The semiconductor package may further include electroplated layers disposed on the exposed top and bottom surfaces of the leads. The bonding wires may be connected to the electroplated layer disposed on the top surfaces of the leads. The electroplated layer may wholly or partially cover the top surfaces of the leads.

The encapsulant may further include a protrusion that extends over the top surface of the leads except the leads. The encapsulant may also further include a protrusion that extends onto portions of the top surfaces of the leads that are not covered with the electroplated layer. The electroplated layer, which partially covers the top surface of the leads, may be preferably formed on the portions of the top surfaces of the leads adjacent to the semiconductor chip in order to facilitate the connection of the electroplated layer with the bonding wires. The protrusion of the encapsulant may extend to cover the electroplated layer formed on the top surfaces of the leads.

Meanwhile, the semiconductor chip may be adhered to a top surface of the mounting portion using an adhesive, and the encapsulant of the semiconductor package may further include a protrusion formed on the top surface of the mounting portion around the semiconductor chip or an extended portion of the encapsulant extended toward the semiconductor chip inwardly around the semiconductor chip in order to prevent the adhesive from overflowing toward the leads.

According to another aspect of the present invention, there is provided a method of fabricating a semiconductor package. The method includes preparing a lead frame including a plurality of units, each unit including a plurality of leads that protrude toward an inner space. Each of the units is molded using an encapsulant to expose top and bottom surfaces of the leads and encapsulate sidewalls and a bottom of the semiconductor package. A semiconductor chip including a plurality of bonding pads is adhered onto the bottom of the semiconductor package between the leads. The leads are wire-bonded to the bonding pads of the semiconductor chip. Thereafter, a transparent plate is adhered over the leads a predetermined space apart from the semiconductor chip. Each of the units is separated from the lead frame using a singulation process.

The lead frame may include a lead frame pad, which is separated from the leads and disposed between the leads. In this case, the semiconductor chip may be adhered onto the lead frame pad. When the lead frame does not include the lead frame pad, the semiconductor chip may be adhered to a planar surface of a bottom of the encapsulant that is formed during the molding process.

After molding each of the units and before adhering the semiconductor chip, the method may further include forming an electroplated layer on the exposed top surfaces of the leads in order to reinforce adhesion of the leads with the semiconductor chip. Also, after adhering the transparent plate over the leads, the method may further include forming a solder electroplated layer on the exposed bottom surfaces of the leads.

Alternatively, after molding each of the units and before adhering the semiconductor chip, the method may further include forming electroplated layers comprising for example, PPF(Ni/Pd/Au), Au and Ag, on the exposed bottom and top surfaces of the leads simultaneously.

The transparent plate may be adhered separately over the leads in each of the units. Alternatively, the transparent plate may be adhered over the leads throughout the entire lead frame and separated into portions corresponding to the respective units during the singulation process.

According to yet another aspect of the present invention, there is provided a semiconductor package module for an image sensor. The module includes a printed circuit board (PCB); a semiconductor package mounted on the PCB; and a lens holder disposed over the semiconductor package. The semiconductor package includes a mounting portion on which a semiconductor chip is mounted. The mounting portion supports the semiconductor chip. A semiconductor chip includes a plurality of bonding pads disposed along an edge thereof and is adhered onto the mounting portion. A plurality of leads are spaced apart from a sidewall of the semiconductor chip and have a greater height than the semiconductor chip. An encapsulant fixes the mounting portion and the leads, encapsulates a bottom surface and a sidewall of the semiconductor package, and exposes top and bottom surfaces of the leads. Bonding wires connect the bonding pads of the semiconductor chip with the exposed top surfaces of the leads. A transparent plate is adhered over the leads with a predetermined space apart from the semiconductor chip.

The lens holder may be adhered onto the top surfaces of the leads of the semiconductor package or directly adhered on the PCB.

According to still another aspect of the present invention, there is provided a semiconductor package including a semiconductor chip including a plurality of bonding pads. A plurality of leads are spaced apart from a sidewall of the semiconductor chip and have bottom surfaces that are substantially on the same plane with a bottom surface of the semiconductor chip. A plurality of bonding wires electrically connect the bonding pads of the semiconductor chip with the leads. An encapsulant fixes and encapsulates the semiconductor chip, the bonding wires, and the leads, and exposes the bottom surface of the semiconductor chip and the bottom surfaces of the leads.

The encapsulant may be formed of a transparent material. The encapsulant may be higher than top surfaces of the leads. Also, the leads may be higher or lower than the semiconductor chip.

The semiconductor package may further include an upper electroplated layer disposed on exposed top surfaces of the leads; and a lower electroplated layer disposed on the exposed bottom surfaces of the leads. The bonding wires may be connected to the upper electroplated layer disposed on the top surfaces of the leads.

The semiconductor package may further include a semiconductor chip pad disposed on the bottom surface of the semiconductor chip. A bottom surface of the semiconductor chip pad may be substantially on the same plane with the bottom surfaces of the leads.

Furthermore, a semiconductor package includes at least two semiconductor packages that are stacked vertically using an adhesive, wherein each semiconductor package is the same as the above-described semiconductor package.

According to further another aspect of the present invention, there is provided a method of fabricating a semiconductor package. The method includes preparing a lead frame including a plurality of leads that protrude toward an inner space. A tape is adhered onto a bottom surface of the lead frame. A semiconductor chip is adhered onto the tape exposed in the inner space of the lead frame. The leads are electrically connected with the semiconductor chip using bonding wires. The leads, the bonding wires, and the semiconductor chip are encapsulated using an encapsulant. The tape is removed from the semiconductor chip.

Before adhering the tape onto the bottom surface of the lead frame, the method may further include forming an upper electroplated layer on top surfaces of the leads and forming a lower electroplated layer on bottom surfaces of the leads. Before removing the tape, the lead frame may be separated into respective semiconductor packages using a singulation process.

According to still further another aspect of the present invention, there is provided a semiconductor package module for an image sensor. The module includes a semiconductor package; and a lens holder disposed over the semiconductor package. The semiconductor package includes a semiconductor chip including a plurality of bonding pads. A plurality of leads are spaced apart from a sidewall of the semiconductor chip and have bottom surfaces that are substantially on the same plane with a bottom surface of the semiconductor chip. A plurality of bonding wires electrically connect the bonding pads of the semiconductor chip with the leads. An encapsulant fixes and encapsulates the semiconductor chip, the bonding wires, and the leads and exposes the bottom surface of the semiconductor chip and the bottom surfaces of the leads.

The semiconductor package module may further include a PCB to which the semiconductor package is adhered. The PCB may include an opening having a greater dimension than the semiconductor chip of the semiconductor package, and the semiconductor package may be adhered onto a bottom surface of the PCB.

### ADVANTAGEOUS EFFECTS

The present invention can be widely used for semiconductor packages, particularly, semiconductor package modules for image sensors. Above all, according to the present invention, lightweight and simply configured semiconductor packages can be fabricated using a simple process at low fabrication cost.

### DESCRIPTION OF THE DRAWINGS

FIG. 1 is a cross sectional view of a conventional ceramic semiconductor package.

FIG. 2 is a cross sectional view of another conventional plastic semiconductor package.

FIGS. 3A through 3C are a cross sectional view, a plan view, and a bottom view, respectively, of a semiconductor package according to an embodiment of the present invention.

FIG. 3D is a cross sectional view of a modified embodiment of the semiconductor package shown in FIG. 3A.

FIGS. 4A through 4C are a cross sectional view, a plan view, and a bottom view, respectively, of a semiconductor package according to another embodiment of the present invention.

FIG. 4D is a cross sectional view of a modified embodiment of the semiconductor package shown in FIG. 4A.

FIG. 4E is a cross sectional view of another modified embodiment of the semiconductor package shown in FIG. 4A.

FIGS. 5A and 5B are a cross sectional view and a plan view of a semiconductor package according to yet another embodiment of the present invention.

FIG. 6 is a cross sectional view of a semiconductor package according to still another embodiment of the present invention.

FIG. 7 is a cross sectional view showing a combination of a semiconductor package according to further another embodiment of the present invention with a camera holder.

FIG. 8 is a cross sectional view of a printed circuit board (PCB) on which the semiconductor package of FIG. 3A is mounted.

FIG. 9A is a plan view of a lead frame used for fabricating the semiconductor package of FIG. 3A.

FIGS. 9B through 9K are cross sectional views taken along line A-A′ of FIG. 9A, which exemplarily illustrate a process of fabricating the semiconductor package of FIG. 3A.

FIGS. 10A through 10C are cross sectional views taken along line A-A′ of FIG. 9A, which exemplarily illustrate another process of fabricating the semiconductor package of FIG. 3A.

FIGS. 11A through 11C are a plan view, a bottom view, and a cross sectional view, respectively, of a semiconductor package according to further another embodiment of the present invention.

FIG. 12 is a cross sectional view of a modified embodiment of the semiconductor package shown in FIG. 11C.

FIG. 13 is a cross sectional view of a semiconductor package according to further another embodiment of the present invention, which is fabricated by stacking two semiconductor packages as shown in FIG. 12.

FIG. 14 is a cross sectional view of a semiconductor package according to further another embodiment of the present invention, which is fabricated by adhering the semiconductor package of FIG. 12 to a bottom surface of a PCB.

FIG. 15 is a cross sectional view of a modified embodiment of the semiconductor package shown in FIG. 12.

FIG. 16 is a cross sectional view of another modified embodiment of the semiconductor package shown in FIG. 11C.

FIGS. 17A and 17B are a cross sectional view and a bottom view, respectively, of yet another modified embodiment of the semiconductor package shown in FIG. 11C.

FIG. 18 is a cross sectional view of a semiconductor package module for an image sensor, in which a semiconductor package according to further another embodiment of the present invention is combined with a camera holder.

FIG. 19 is a plan view of a lead frame used for fabricating the semiconductor package shown in FIG. 11C.

FIGS. 20A through 20F are cross sectional views taken along line C-C′ of FIG. 19, which exemplarily illustrate a process of fabricating the semiconductor package shown in FIG. 1C.

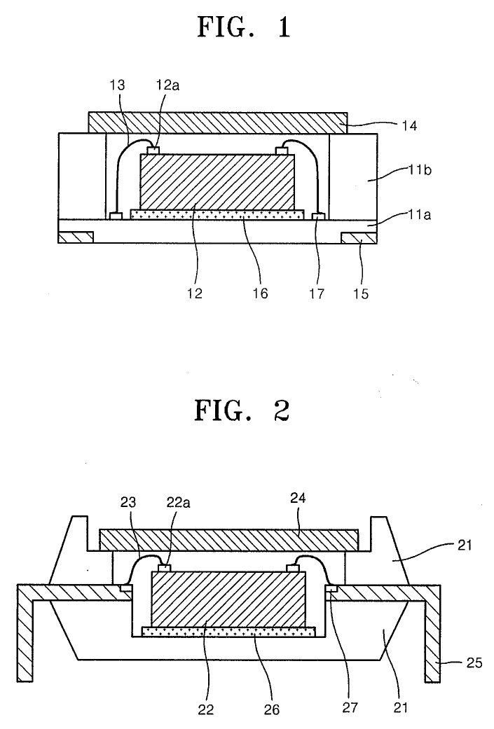

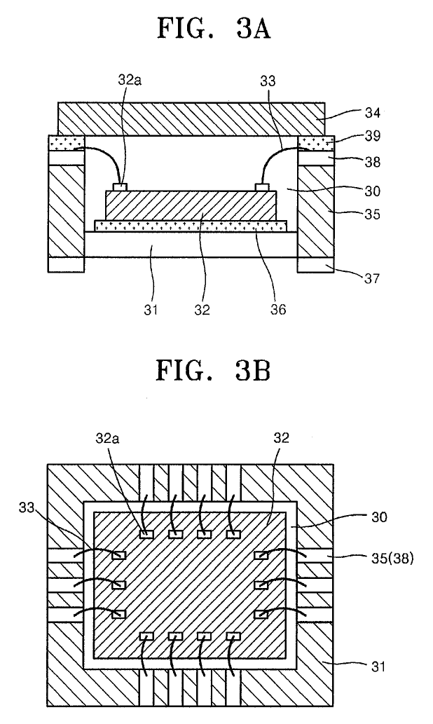

### BEST MODE FOR CARRYING OUT THE INVENTION

The present invention will now be described more fully hereinafter with reference to the accompanying drawings, in which exemplary embodiments of the invention are shown. This invention may, however, be embodied in different forms and should not be construed as limited to the embodiments set forth herein. Rather, these embodiments are provided so that this disclosure is thorough and complete and fully conveys the scope of the invention to those skilled in the art. In the drawings, the thicknesses of layers and regions are exaggerated for clarity. It will also be understood that when a layer is referred to as being “on” another layer or substrate, it can be directly on the other layer or substrate or intervening layers may also be present. The same reference numerals are used to denote the same elements throughout the specification.

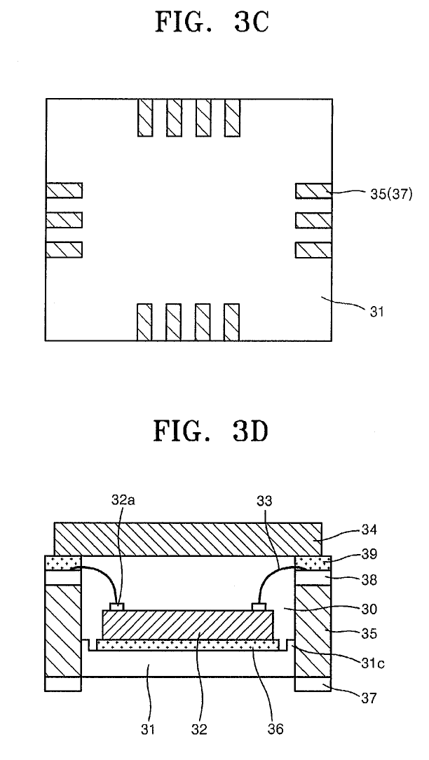

FIGS. 3A through 3C are a cross sectional view, a plan view, and a bottom view, respectively, of a semiconductor package for an image sensor according to an embodiment of the present invention. Specifically, FIG. 3B is a plan view of the semiconductor package before a transparent plate 34 is adhered or before an upper electroplated layer 38 is formed, and FIG. 3C is a bottom view showing a bottom surface of the semiconductor package before or after a lower electroplated layer 37 is formed. Each of the upper and lower electroplated layers 38 and 37 is formed on an exposed portion of a lead 35.

Referring to FIGS. 3A through 3C, a bottom portion of the semiconductor package includes an encapsulant 31 with a predetermined thickness and a planar top surface. A sidewall portion of the semiconductor package is formed on each of sides of the bottom portion of the semiconductor package to a predetermined height. The sidewall portion of the semiconductor package includes a plurality of leads 35 with a predetermined height and the encapsulant 31 used for fixing the leads 35. The encapsulant 31 constituting the bottom portion of the semiconductor package is integrally formed with the encapsulant 31 constituting the sidewall portion thereof. For example, the encapsulant 31 may be formed of epoxy molding compound (EMC) to encapsulate the bottom and sidewall portions of the semiconductor package. Top and bottom surfaces of the leads 35 that are encapsulated and fixed by the encapsulant 31 are not encapsulated by the encapsulant 31 but exposed. The encapsulant 31 constituting the bottom portion of the semiconductor package may function as a mounting portion on which a semiconductor chip 32 is mounted using an adhesive 36. The adhesive 36 may be, for example, an epoxy-based adhesive.

Meanwhile, the leads 35 that are spaced apart from the semiconductor chip 32 may be higher than the semiconductor chip 32. That is, the height of the leads 35 or the height of the mounting portion may be appropriately selected such that the top surfaces of the leads 35 are higher than a top surface of the semiconductor chip 32.

The semiconductor chip 32 includes a CMOS image sensor (CIS), which is a kind of a photodiode (PD) used in cameras for portable phones and CCDs. A plurality of bonding pads 32a are formed along an edge of the top surface of the semiconductor chip 32. The bonding pads 32a may be electrically connected to an external circuit. The bonding pads 32a are electrically connected to the exposed top surfaces of the leads 35 by bonding wires 33. In the present invention, the upper electroplated layer 38, which is formed of a metal such as gold (Au) or silver (Ag), is formed on the exposed top surfaces of the leads 35 in order to ensure reliable adhesion of the leads 35 with the bonding wires 33 formed of a metal such as aluminum (Al) or gold (Au). In FIG. 3B, reference numeral 35(38) shows a case where the upper electroplated layer 38 is formed on the leads 35. Meanwhile, a solder paste layer (71 in FIG. 8) and the lower electroplated layer 37 are formed on the exposed bottom surfaces of the leads 35. The lower electroplated layer 37 may be, for example, an SnPb solder electroplated layer, in order to improve solder adhesion of the solder paste layer 71 with the leads 35. The present invention is not limited to the above description, and the upper electroplated layer 38 may be a pre-plated frame (PPF) electroplated layer that is formed of nickel (Ni), palladium (Pd), instead of a metal such as gold (Au) or silver (Ag). Also, the lower electroplated layer 37 may be not an SnPb solder electroplated layer but a PPF electroplated layer formed of Ni, Pd, and Au.

The transparent plate 34, for example, a glass plate, which allows light to pass therethrough, may be adhered onto the upper electroplated layer 38 by an adhesive 39. Thus, a leadless semiconductor package for an image sensor, which includes a specific encapsulated space 30, is completed.

FIG. 3D is a cross sectional view of a modified example of the semiconductor package shown in FIG. 3A.

The semiconductor package of FIG. 3D is generally similar to the semiconductor package of FIG. 3A except that an encapsulant 31 includes a protrusion 31c that is formed around the semiconductor chip 32 on a part of the top surface of a bottom portion of the encapsulant 31 on which a semiconductor chip 32 is mounted. When the semiconductor chip 32 is brought into contact with the top surface of the bottom portion of the encapsulant 31, an adhesive 36, which is a conductive adhesive such as an Ag epoxy adhesive, may overflow and contact adjacent leads 35. In this case, the elevation 31c prevents the occurrence of short circuits between the adhesive 36 and the leads 35.

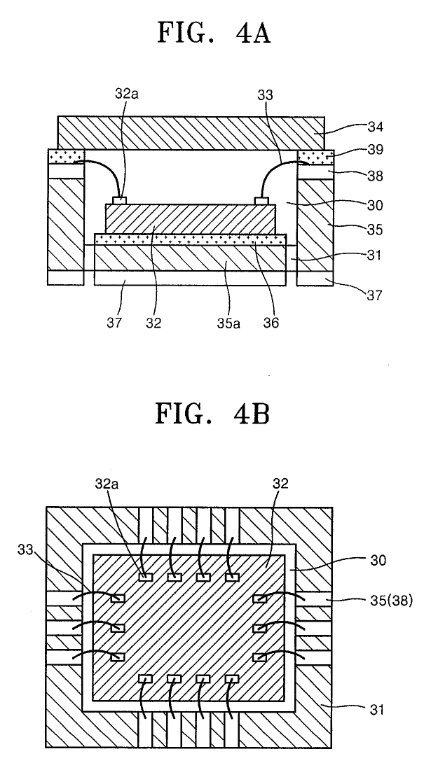

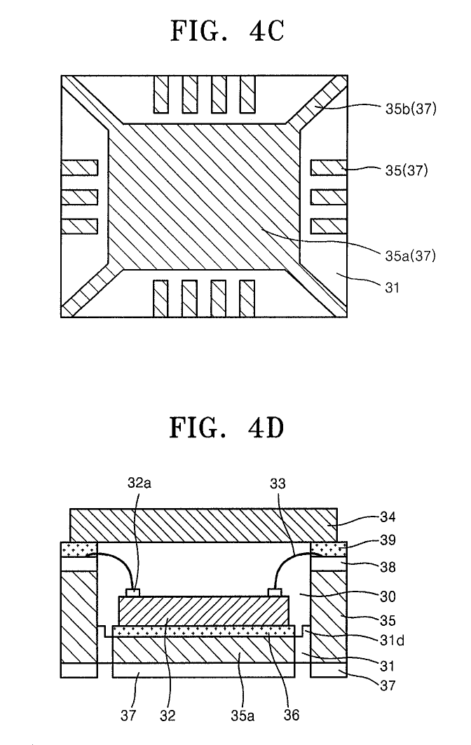

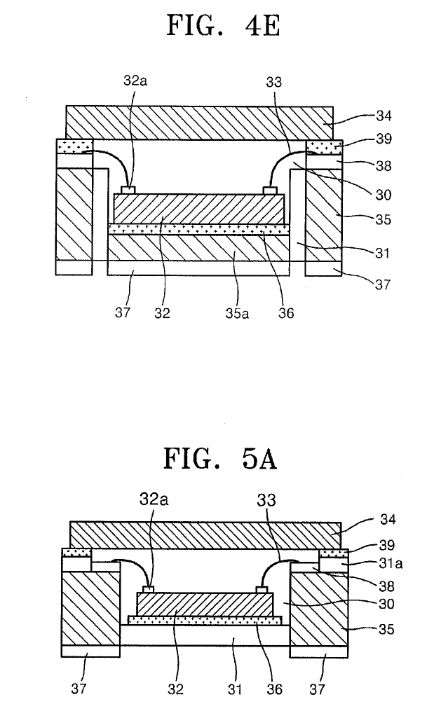

FIGS. 4A through 4C are a cross sectional view, a plan view, and a bottom view, respectively, of a semiconductor package according to another embodiment of the present invention. Specifically, FIG. 4B is a plan view of the semiconductor package before a transparent plate 34 is adhered or before an upper electroplated layer 38 is formed, and FIG. 4C is a bottom view showing a bottom surface of the semiconductor package. In FIGS. 4A through 4C, the same reference numerals are used to denote the same elements as in FIGS. 3A through 3C, and another description of the same elements will be partially omitted.

Referring to FIGS. 4A through 4C, a lead frame pad 35a with a predetermined thickness and a planar top surface is formed on the center of a bottom portion of the semiconductor package. The lead frame pad 35a may be formed of the same material as the leads 35. Also, the lead frame pad 35a may be half-etched to be lower than the leads 35 such that a semiconductor chip 32 is reliably mounted and the semiconductor package is fabricated to be thin and simple. A lead frame connection bar 35b is installed at each corner of the lead frame pad 35a in order to connect the lead frame pad 35a with a main body of a lead frame. A sidewall portion of the semiconductor package is formed on each of sides of the bottom portion of the semiconductor package to a predetermined height. The sidewall portion of the semiconductor package includes a plurality of leads 35 with a predetermined height and an encapsulant 31 used for fixing the leads 35. The bottom and sidewall portions of the semiconductor package are integrally formed by the lead frame pad 35a, the connection bar 35b, and the encapsulant 31 for fixing and encapsulating the leads 35. Top and bottom surfaces of the leads 35 that are encapsulated and fixed by the encapsulant 31 are not encapsulated by the encapsulant 31 but exposed. The lead frame pad 35a formed on the bottom portion of the semiconductor package may function as a mounting portion on which a semiconductor chip 32 is mounted. Thus, the lead frame pad 35 may strongly support the semiconductor chip 32 and allows heat generated during operation of the semiconductor chip 32 to be efficiently emitted.

Meanwhile, a lower electroplated layer 37 is formed on the exposed bottom surfaces of the leads 35 in order to improve solder adhesion of a solder paste layer (71 in FIG. 8) with the leads 35. The lower electroplated layer 37 may be, for example, an SnPb solder electroplated layer. Simultaneously, the lower electroplated layer 37 is formed also on the exposed bottom surface of the lead frame pad 35a.

FIG. 4D is a cross sectional view of a modified example of the semiconductor package shown in FIG. 4A.

The semiconductor package of FIG. 4D is generally similar to the semiconductor package of FIG. 4A except that an encapsulant 31 includes a protrusion 31d that is formed around the lead frame pad 35a on which a semiconductor chip 32 is mounted. When the semiconductor chip 32 is brought into contact with the top surface of the lead frame pad 35a, an adhesive 36, which is a conductive adhesive such as an Ag epoxy adhesive, may overflow and contact adjacent leads 35. In this case, the elevation 31d prevents the occurrence of short circuits between the adhesive 36 and the leads 35.

FIG. 4E is a cross sectional view of another modified example of the semiconductor package shown in FIG. 4A.

The semiconductor package of FIG. 4E is generally similar to the semiconductor package of FIG. 4D except that an encapsulant 31 includes an extended portion that extends toward the semiconductor chip 32 inwardly, around the sidewall of the lead frame pad 35a and the semiconductor chip 32. When the semiconductor chip 32 is brought into contact with the top surface of the lead frame pad 35a, an adhesive 36, which is a conductive adhesive such as an Ag epoxy adhesive, may overflow and contact adjacent leads 35. In this case, the extended portion can prevents the occurrence of short circuits between the adhesive 36 and the leads 35.

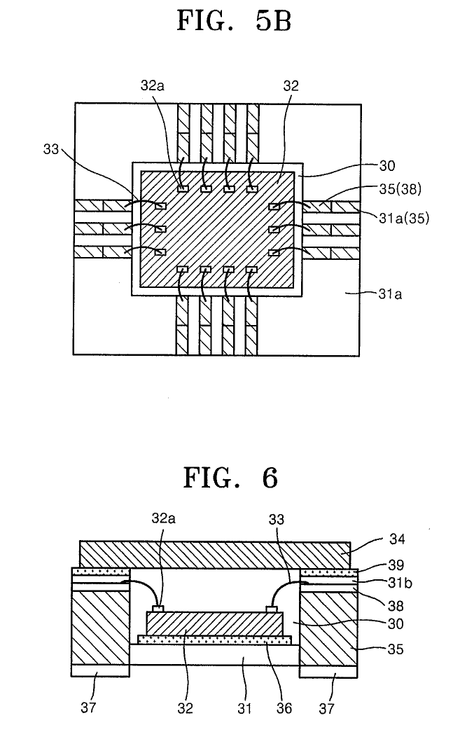

FIGS. 5A and 5B are a cross sectional view and a plan view of a semiconductor package according to yet another embodiment of the present invention. FIG. 5B is a plan view before a transparent plate 34 is adhered. In FIGS. 5A and 5B, the same reference numerals are used to denote the same elements as in FIGS. 3A through 3D, and another description of the same elements will be partially omitted.

Referring to FIGS. 5A and 5B, bottom and sidewall portions of the semiconductor package are similar to the bottom and sidewall portions of the semiconductor package as described with reference to FIG. 3A. However, in the present embodiment, an upper electroplated layer 38 is formed only on portions of exposed top surfaces of leads 35, while an encapsulant protrusion 31a, which extends from an encapsulant 31, is formed on the remaining portions of the exposed top surfaces of the leads 35 on which the upper electroplated layer 38 is not formed. Also, an adhesive 39 is formed only on a top surface of the encapsulant protrusion 31a. In order to facilitate a wire bonding process using bonding wires 33, the upper electroplated layer 38 is formed on the top surfaces of the leads 35 adjacent to a semiconductor chip 32. Thus, since the adhesive 39 is not formed on the upper electroplated layer 38, it can be easily inspected if the bonding wires 33 are reliably bonded to the upper electroplated layer 38 or not.

A lower electroplated layer 37, for example, an SnPb solder electroplated layer, is formed on exposed bottom surfaces of the leads 35 in order to improve solder adhesion.

Although not shown in FIG. 5A, in order to prevent the occurrence of short circuits between the adhesive 36 and the leads 35 caused by the overflow of the adhesive 36, the encapsulant 31 may further include a protrusion that protrudes to a predetermined height around the semiconductor chip 32 on the mounting portion of the encapsulant 31 on which the semiconductor chip 32 is mounted.

FIG. 6 is a cross sectional view of a semiconductor package according to still another embodiment of the present invention.

The semiconductor package of FIG. 6 differs from the semiconductor package of FIG. 3A in that another encapsulant 31b is further formed on an upper electroplated layer 38.

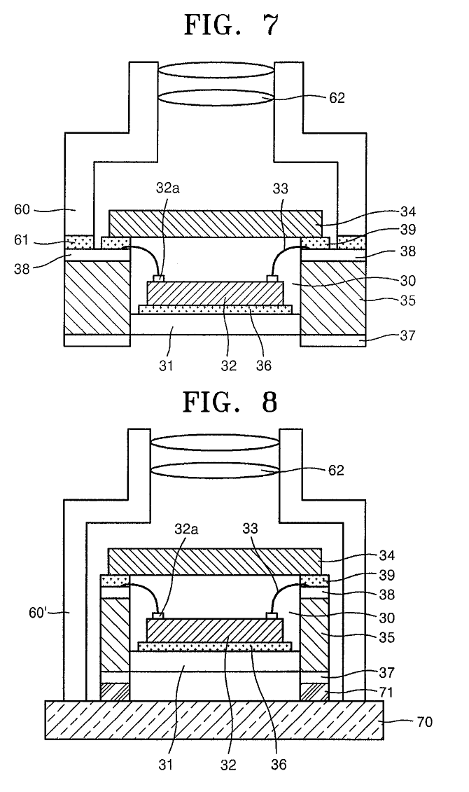

FIG. 7 is a cross sectional view showing combination of a semiconductor package according to further another embodiment of the present invention with a camera holder.

Referring to FIG. 7, bottom and sidewall portions of the semiconductor package are similar to the bottom and sidewall portions of the semiconductor package as described with reference to FIG. 3A. Although not shown in FIG. 7, a lead frame pad 35a may be formed on the bottom portion of the semiconductor package so that a semiconductor chip 32 can be mounted on the lead frame pad 35a, as described with reference to FIG. 4A. In the present embodiment, an upper electroplated layer 38 is formed on exposed top surfaces of leads 35, and a transparent plate 34 is adhered onto a portion of the upper electroplated layer 38 using an adhesive 39. A lens holder 60 is adhered using an adhesive 61 onto the remaining portion of the upper electroplated layer 38 on which the transparent plate 34 is not formed. A lens 62 for cameras is combined with the lens holder 60. The semiconductor package with which the lens holder 60 is combined may be mounted on a PCB by means of a solder paste layer (71 of FIG. 8) as will be described later.

FIG. 8 is a cross sectional view of a PCB 70 on which the semiconductor package of FIG. 3A is mounted.

Referring to FIG. 8, a solder paste layer 71 is formed on a lower electroplated layer 37, and the semiconductor package is mounted on the PCB 70. A lens holder 60′ is adhered onto the PCB 70 to surround the semiconductor package. A lens 62 for cameras is combined with the lens holder 60′.

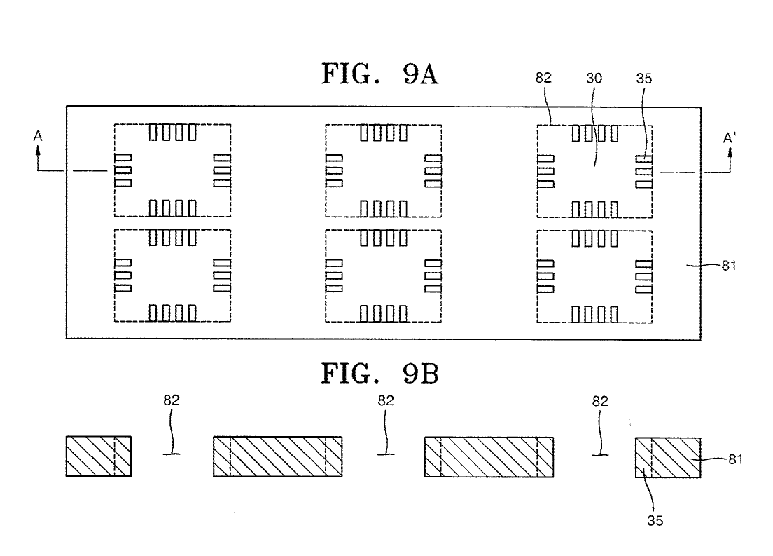

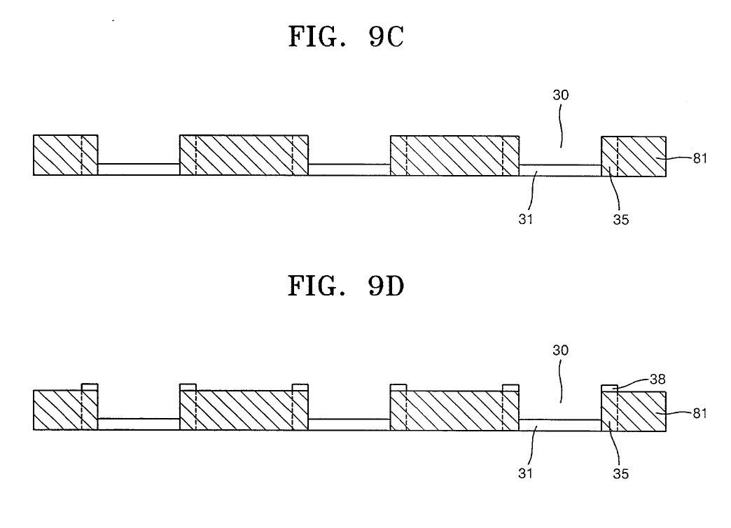

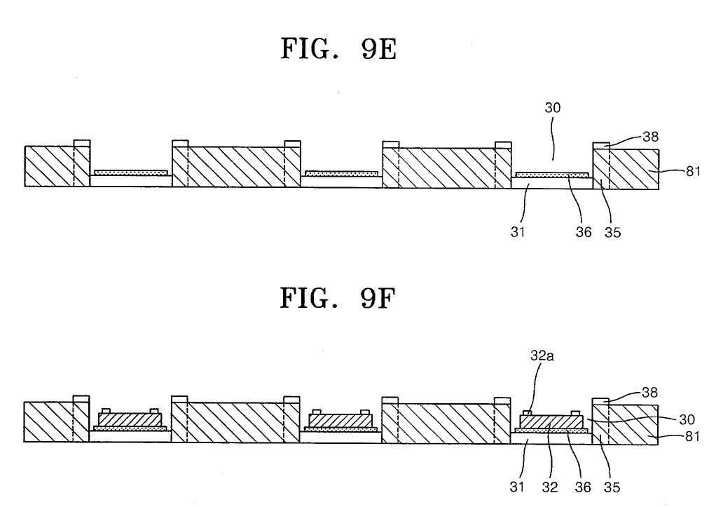

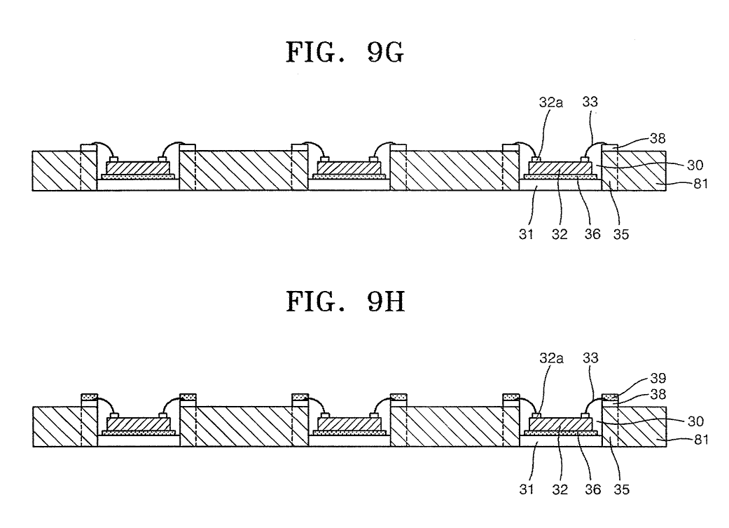

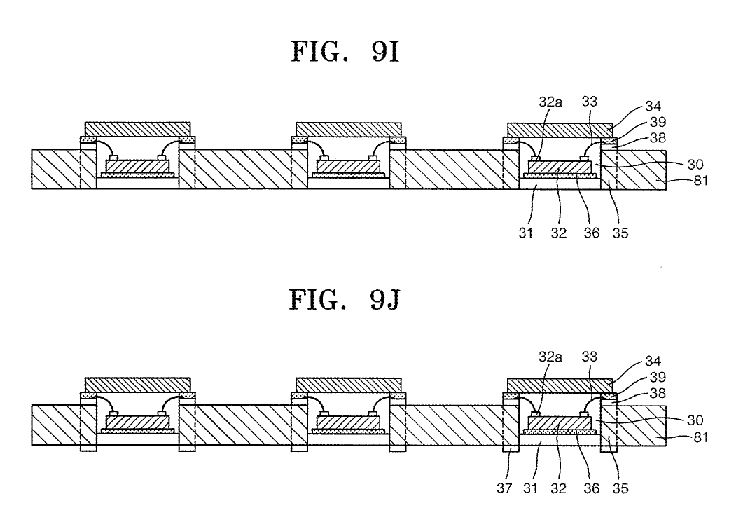

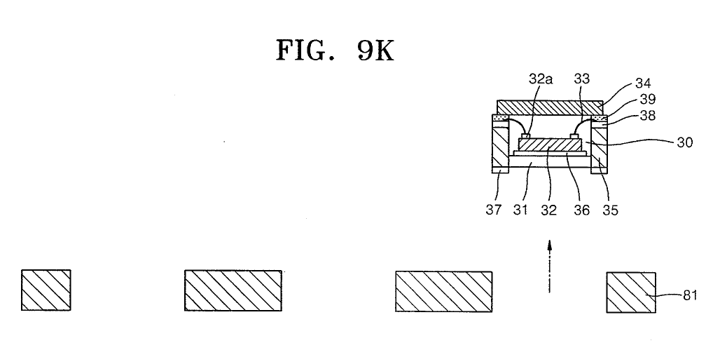

FIG. 9A is a plan view of a lead frame 81 used for fabricating the semiconductor 15 package of FIG. 3A, and FIGS. 9B through 9K are cross sectional views taken along line A-A′ of FIG. 9A, which exemplarily illustrate a process of fabricating the semiconductor package of FIG. 3A.

Hereinafter, a process of fabricating a semiconductor package according to an embodiment of the present invention will be described in detail with reference to FIGS. 9A through 9K.

Referring to FIGS. 9A and 9B, the lead frame 81 including a plurality of units 82 is prepared. The lead frame 81 may be formed of any one of copper, copper compounds comprising iron or nickel. A plurality of leads 35 are formed in each of the units 82. Each of the leads 35 extends by a predetermined length toward a central space 30. In the present invention, the thickness of the lead frame 81, namely, the thickness of the lead 35, may be greater than the thickness of a semiconductor chip 32 as illustrated in FIG. 3A and range from several tens to several hundred μm or higher.

Referring to FIGS. 9B and 9C, an epoxy molding process is performed to form an encapsulant 31 made of EMC. The encapsulant 31 constitutes a bottom portion of the semiconductor package under the central space 30 between the leads 35 in each of the units 82. Simultaneously, the encapsulant 31 is filled between the leads 35 to fix the leads 35 and form a sidewall portion of the semiconductor package.

Referring to FIG. 9D, an upper electroplated layer 38 is selectively formed only on top surfaces of the leads 35 that are exposed by the encapsulant 31.

Referring to FIG. 9E, an adhesive 36 is selectively formed on a top surface of the encapsulant 31 that constitutes the bottom portion of the semiconductor package.

Referring to FIG. 9F, the semiconductor chip 32 is die-bonded to the adhesive 36 formed on the encapsulant 31. The semiconductor chip 32, which is used for an image sensor, includes a plurality of bonding pads 32a that are formed along an edge of a top surface of the semiconductor chip 32.

Referring to FIG. 9G, the top surfaces of the leads 53, which are exposed by the encapsulant 31, are wire-bonded to the bonding pads 32a by bonding wires 33 formed of aluminum (Al) or gold (Au).

Referring to FIG. 9H, an adhesive 39 is coated on a top surface of the upper electroplated layer 38.

Referring to FIG. 9I, a transparent plate 34, for example, a glass plate, is mounted on the adhesive 39 in each of the units 82.

Referring to FIG. 9J, a lower electroplated layer 37 is formed on bottom surfaces of the leads 35 that are exposed by the encapsulant 31.

Referring to FIG. 9K, each semiconductor package is separated from the lead frame 81 using a singulation process, thus completing the fabrication of the semiconductor package shown in FIG. 3A.

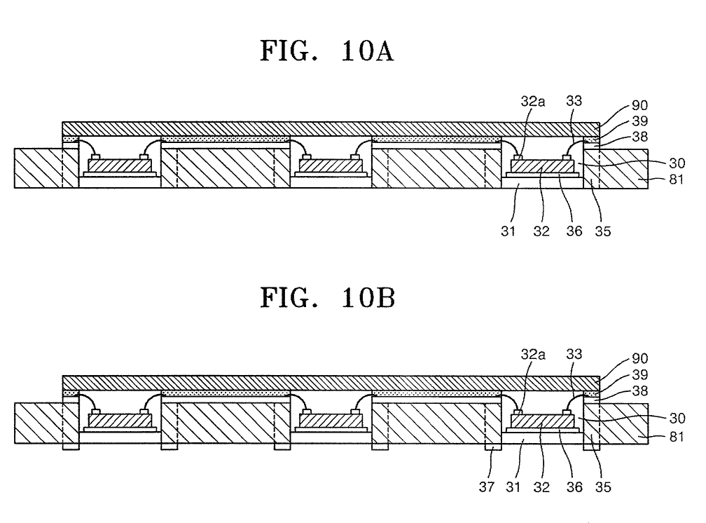

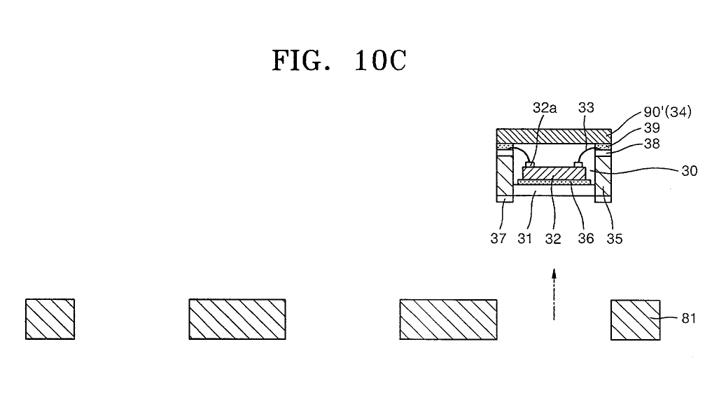

FIGS. 10A through 10C are cross sectional views taken along line A-A′ of FIG. 8A, which exemplarily illustrate another process of fabricating the semiconductor package of FIG. 3A. The processes performed until forming an adhesive 39 on an upper electroplated layer 38 are the same as described with reference to FIGS. 9A through 9H, thus the description will begin with the subsequent processes.

Referring to FIG. 10A, after forming the adhesive 39 on the upper electroplated layer 38, a single transparent plate 90 is adhered to the upper electroplated layer 38 over the entire lead frame 81, unlike described with reference to FIG. 9I.

Referring to FIG. 10B, a lower electroplated layer 37 is selectively formed only on bottom surfaces of leads 35 that are exposed by an encapsulant 31.

Referring to FIG. 10C, each semiconductor package is separated from the lead frame 81 using a singulation process, thus completing the fabrication of the semiconductor package.

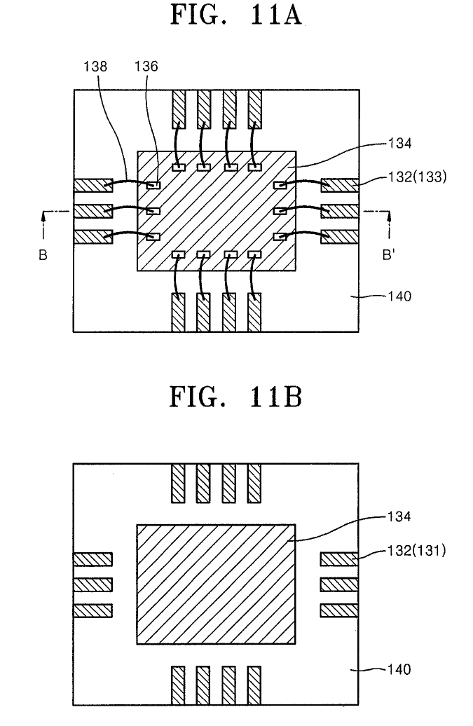

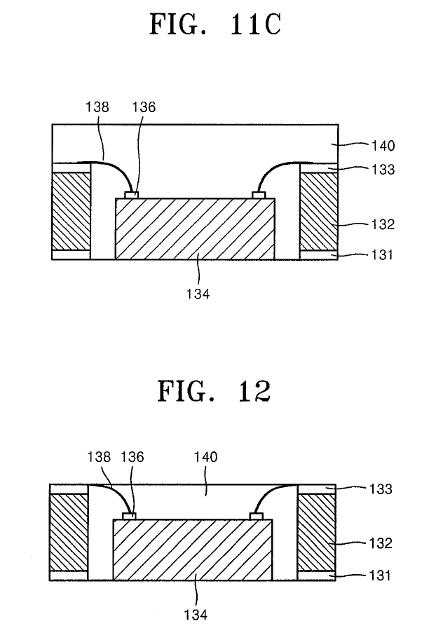

FIGS. 11A through 11C are a plan view, a bottom view, and a cross sectional view, respectively, of a semiconductor package according to further another embodiment of the present invention. In FIGS. 11A and 11B, an upper electroplated layer 133 and a lower electroplated layer 131 are not illustrated for brevity, but their reference numerals 133 and 131 are put in parentheses beside the reference numeral of the leads 132. Also, although the leads 132, bonding wires 138, and a semiconductor chip 134 are covered with an encapsulant 140, the leads 132, the bonding wires 138, and the semiconductor chip 134 are shown in FIG. 11A to illustrate the arrangement of the leads 132. FIG. 11C is a cross sectional view taken along line B-B′of FIG. 11A.

Referring to FIGS. 11A through 11C, a semiconductor chip 134 is disposed on the center of the semiconductor package and enclosed with a plurality of leads 132 apart from the leads 132. A plurality of bonding pads 136 are formed along an edge of a top surface of the semiconductor chip 134. The upper electroplated layer 133 is formed on a top surface of each of the leads 132, and the lower electroplated layer 131 is formed on a bottom surface thereof.

Also, the upper electroplated layer 133 is electrically connected to the bonding pad 136 of the semiconductor chip 134 by the bonding wire 138, and the encapsulant 140 is formed on the resultant structure to encapsulate and fix the leads 132 and the semiconductor chip 134. As illustrated in FIG. 11C, a bottom surface of the semiconductor chip 134 may be substantially on the same plane with the bottom surfaces of the leads 132 or a bottom surface of the lower electroplated layer 131 formed on the bottom surfaces of the leads 132.

The encapsulant 140 is formed using a transparent material, for example, EMC. In the present embodiment, the height of the leads disposed around the semiconductor chip 134 spaced apart from the semiconductor chip 134 is higher than the height of a top surface of the semiconductor chip 132. The semiconductor chip 134 includes a CIS, which is a kind of a PD used in cameras for portable phones and CCDs. A plurality of bonding pads 136 are formed along an edge of the top surface of the semiconductor chip 134 and electrically connected to an external circuit. The bonding pads 136 are electrically connected to the exposed top surfaces of the leads 132 by the bonding wires 138, respectively. In the present invention, the upper electroplated layer 133 is formed on the exposed top surfaces of the leads 132 in order to improve adhesion of the leads 132 with the bonding wires 138 formed of Al or Au. In this case, the upper electroplated layer 133 may be formed of a metal such as Au and Ag or an alloy such as NiPd.

Meanwhile, the lower electroplated layer 131, which is formed of the same material as the upper electroplated layer 133, may be formed on the exposed bottom surfaces of the leads 132. Alternatively, an SnPb solder electroplated layer may be formed as the lower electroplated layer 131 in order to improve solder adhesion of the semiconductor package with a substrate (not shown) on which the semiconductor package will be mounted. In another case, the upper electroplated layer 133 may be a PPF electroplated layer formed of Ni, Pd, and Au instead of Au or Ag. Also, the lower electroplated layer 131 may be a PPF electroplated layer formed of Ni, Pd, and Au, instead of an SnPb solder electroplated layer.

FIG. 12 is a cross sectional view of a modified example of the semiconductor package shown in FIG. 11C.

The semiconductor package of FIG. 12 is generally similar to the semiconductor package of FIG. 11C except that an encapsulant 140 is almost as high as the leads 132 disposed around a semiconductor chip 134 or an upper electroplated layer 133 disposed on top surfaces of the leads 132.

FIG. 13 is a cross sectional view of a stacked semiconductor package fabricated by stacking two semiconductor packages as shown in FIG. 12. In the present invention, two or more semiconductor packages may be vertically stacked for forming a stacked semiconductor package using an adhesive 142, therebetween.

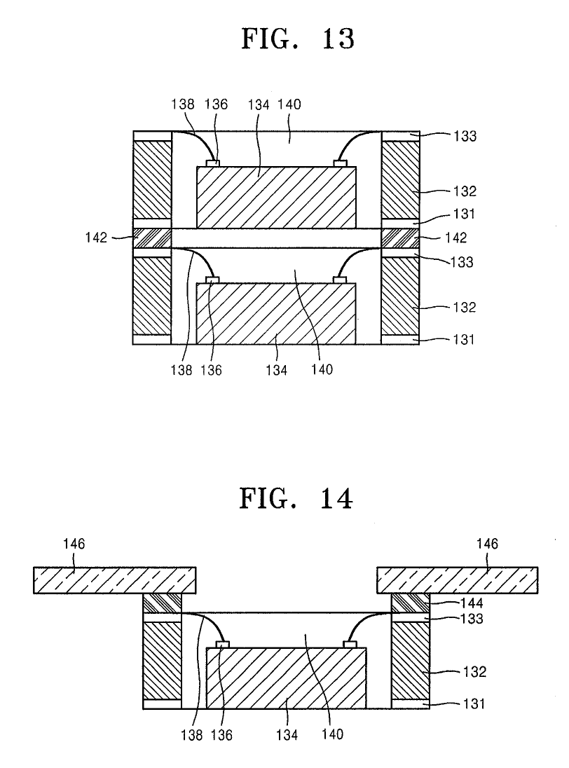

FIG. 14 is a cross sectional view of a semiconductor package fabricated by adhering the semiconductor package of FIG. 12 to a bottom surface of a PCB 146 using an adhesive 144.

Referring to FIG. 14, an opening for transmitting light is formed in the PCB 146. In order to elevate light transmission efficiency, the opening may be formed to a greater dimension than a semiconductor chip 134 of the semiconductor package adhered to the bottom surface of the PCB 146.

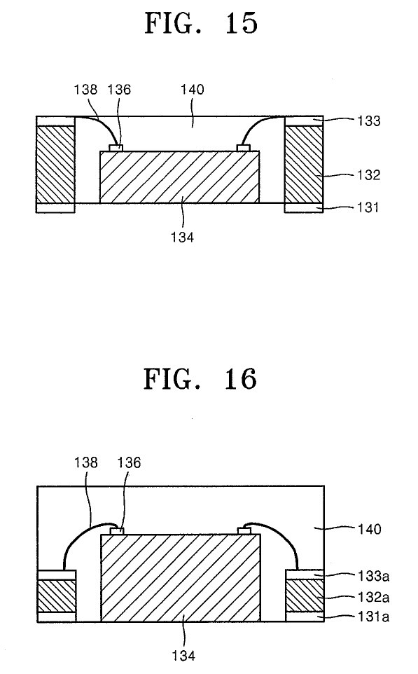

FIG. 15 is a cross sectional view of a modified example of the semiconductor package shown in FIG. 12.

The semiconductor package of FIG. 15 is generally similar to the semiconductor package of FIG. 12 except that a bottom surface of a semiconductor chip 134 is on the same plane with bottom surfaces of leads 132, and a lower electroplated layer 131 is further formed on the bottom surfaces of the leads 132.

FIG. 16 is a cross sectional view of another modified example of the semiconductor package shown in FIG. 11C.

The semiconductor package of FIG. 16 is generally similar to the semiconductor package of FIG. 11C except that the height of leads 132a disposed around a semiconductor chip 134 or the height of an upper electroplated layer 133a formed on top surfaces of the leads 132a is smaller than the height of the semiconductor chip 134.

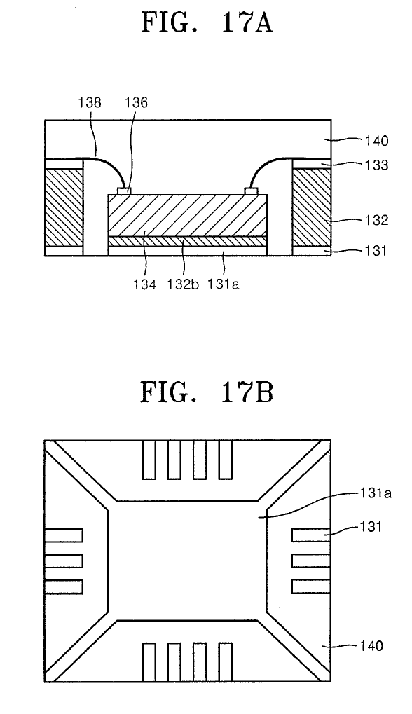

FIGS. 17A and 17B are a cross sectional view and a bottom view, respectively, of yet another modified example of the semiconductor package shown in FIG. 11C.

The semiconductor package of FIGS. 17A and 17B is generally similar to the semiconductor package of FIGS. 11B and 11C except for the shape of a lead frame. Specifically, a die pad 132b is formed between leads 132 in the lead frame, and a semiconductor chip 134 is mounted on the die pad 132b using an adhesive (not shown). The die pad 132b is formed of the same material as the leads 132 to a less height than the leads 132. Thus, the semiconductor package of FIGS. 17A and 17B differs from the semiconductor package of FIGS. 11B and 11c in that when a lower electroplated layer 131 is formed on bottom surfaces of the leads 132, a die pad electroplated layer 131a also is formed on a bottom surface of the die pad 132b. In the present embodiment, a bottom surface of the die pad electroplated layer 131a is on the same plane with the bottom surfaces of the leads 132 or a bottom surface of the lower electroplated layer 131 formed on the bottom surfaces of the leads 132.

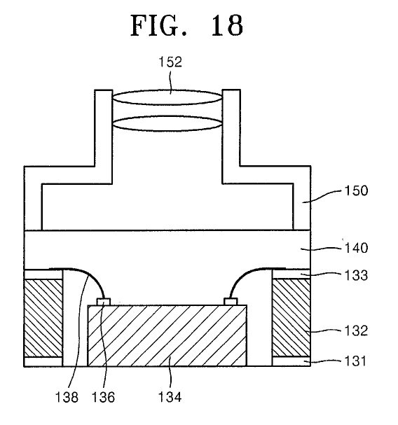

FIG. 18 is a cross sectional view of a semiconductor package module in which a semiconductor package according to further another embodiment of the present invention is combined with a camera holder. In the present embodiment, it is exemplarily described that the semiconductor package is the same as illustrated in FIG. 11C. However, the present invention is not limited thereto and any other semiconductor packages as illustrated in FIGS. 12 through 17A may be also applied to the semiconductor package module of FIG. 18.

Referring to FIG. 18, a lens holder 150 is formed along an edge of the semiconductor package, which is the same as illustrated in FIG. 11C, using an adhesive (not shown). The lens holder 150 is combined with a lens 152 for cameras. The foregoing semiconductor package, which is combined with the lens holder 150, may be mounted on a substrate (not shown), such as a PCB.

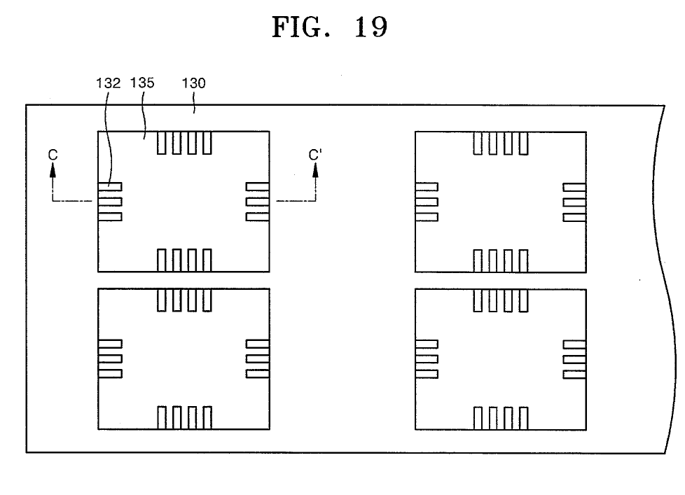

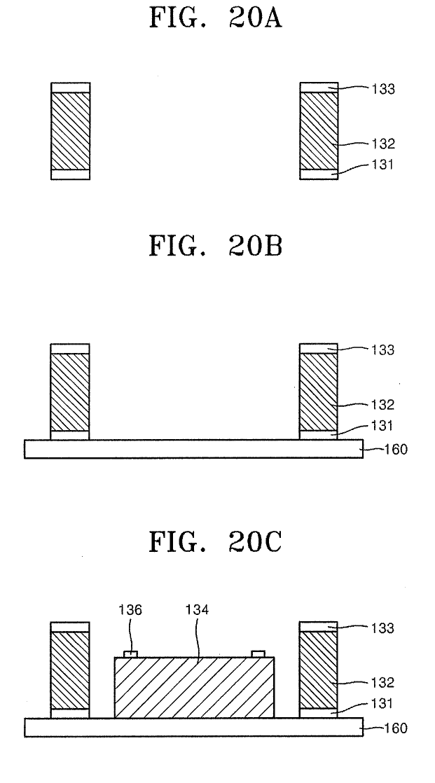

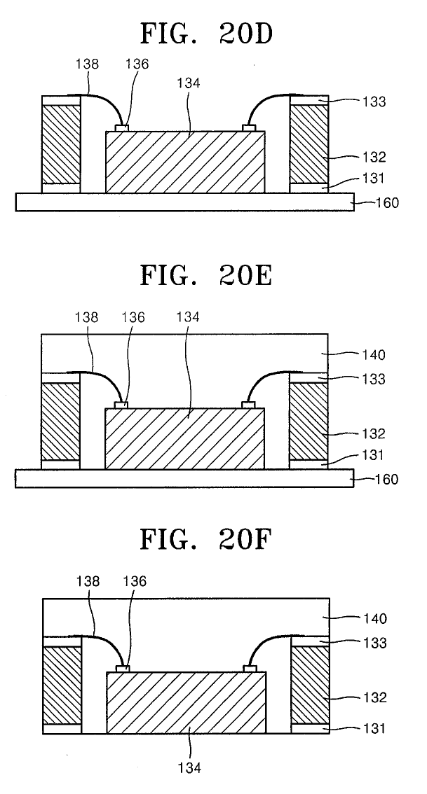

Hereinafter, a process of fabricating a semiconductor package according to an embodiment of the present invention will be described in detail with reference to FIGS. 19 and 20A through 20F.

FIG. 19 is a plan view of a lead frame 130 used for fabricating the semiconductor package shown in FIG. 11C, and FIGS. 20A through 20F are cross sectional views taken along line C-C′ of FIG. 19, which exemplarily illustrate a process of fabricating the semiconductor package shown in FIG. 11C.

Referring to FIG. 19, the lead frame 130 in which a plurality of units are arranged is prepared. The lead frame 130 may be formed of any one of copper, copper compounds comprising iron or nickel. A plurality of leads 132 are formed in each of the units. Each of the leads 132 extends by a predetermined length toward an inward space 135. In the present invention, the thickness of the lead frame 130, namely, the thickness of the lead 132, may be greater than the thickness of a semiconductor chip 134 as illustrated in FIG. 11C and range from several tens to several hundred μm or higher. However, the thickness of leads 132a may be less than the thickness of the semiconductor chip 132 as illustrated in FIG. 16.

Referring to FIG. 20A, an upper electroplated layer 133 is formed on top surfaces of the leads 132, and a lower electroplated layer 131 is formed on bottom surfaces of the leads 132. The upper and lower electroplated layers 133 and 132 may be formed using the same process or separate processes. The upper electroplated layer 133 is formed on the exposed top surfaces of the leads 132 in order to improve adhesion of the leads 132 with bonding wires 138 (refer to FIG. 20D) that are formed of Al or Au. In this case, the upper electroplated layer 133 may be formed of a metal such as Au and Ag or an alloy such as NiPd. Meanwhile, the lower electroplated layer 131, which is formed of the same material as the upper electroplated layer 133, may be formed on the exposed bottom surfaces of the leads 132. Alternatively, an SnPb solder electroplated layer may be formed as the lower electroplated layer 131 in order to improve solder adhesion of the semiconductor package with a substrate (not shown) on which the semiconductor package will be mounted. In another case, the upper electroplated layer 133 may be a PPF electroplated layer that is formed of Ni, Pd, and Au instead of Au or Ag. Also, the lower electroplated layer 131 may not be an SnPb solder electroplated layer but a PPF electroplated layer formed of Ni, Pd, and Au.

Referring to FIG. 20B, an adhesive and flexible tape 160 is adhered onto a bottom surface of the lead frame 130.

Referring to FIG. 20C, the previously formed semiconductor chip 134 is die-bonded to the tape 160 in the inner space 135 formed between the leads 132 in each of the units of the lead frame 130.

Referring to FIG. 20D, bonding pads 136 formed on a top surface of the semiconductor chip 134 are wire-bonded using bonding wires 138 to the upper electroplated layer 133 formed on the top surfaces of the leads 132 so that the bonding pads 136 may be electrically connected to the upper electroplated layer 133.

Referring to FIG. 20E, an encapsulant 140 formed of EMC is formed to fix and encapsulate the semiconductor chip 134, the bonding wires 138, and the leads 132.

Referring to FIG. 20F, after the encapsulant 140 is formed, a singulation process for separating each unit from the lead frame 130 is performed using a blade, and the tape 160 is removed. Thus, the semiconductor package according to the present invention is completed.

While the present invention has been particularly shown and described with reference to exemplary embodiments thereof, it will be understood by those of ordinary skill in the art that various changes in form and details may be made therein without departing from the spirit and scope of the present invention as defined by the following claims. For example, the height of the leads 132 and the height of the encapsulant 140 may be appropriately selected in consideration of the thickness of the semiconductor chip 134. Also, although it is described that the encapsulant 140 is formed of a transparent epoxy material, the present invention is not limited thereto and the encapsulant 140 may be formed of other various molding materials. Further, a process of fabricating the semiconductor package using the lead frame 130 without a die pad is described with reference to FIGS. 19 and 20A through 20F. However, the present invention is not limited thereto and a semiconductor package may be fabricated using a lead frame in which a die pad is formed in an inner space between leads, as described with reference to FIGS. 17A and 17B.

### INDUSTRIAL APPLICABILITY

The present invention can be widely used for semiconductor packages, particularly, semiconductor package modules for a CMOS image sensor (CIS), which is widely used in cameras for portable phones or charge coupled devices (CCDs).

1. A semiconductor package comprising:
a mounting portion on which a semiconductor chip is mounted, wherein the mounting portion supports the semiconductor chip;
a semiconductor chip including a plurality of bonding pads disposed along an edge thereof, wherein the semiconductor chip is adhered onto the mounting portion;
a plurality of leads spaced apart from a sidewall of the semiconductor chip and having a greater height than the semiconductor chip;
an encapsulant for fixing the mounting portion and the leads, encapsulating a bottom surface and a sidewall of the semiconductor package, and exposing top and bottom surfaces of the leads; and
bonding wires for connecting the bonding pads of the semiconductor chip with the exposed top surfaces of the leads.

2. The package of claim 1, wherein the mounting portion is integrally formed with the encapsulant using the same material.

3. The package of claim 1, wherein the mounting portion is formed of the same material as the leads and separated from the leads.

4. The package of claim 1, further comprising electroplated layers disposed on the exposed top and bottom surfaces of the leads,
wherein the bonding wires are connected to the electroplated layer disposed on the top surfaces of the leads.

5. The package of claim 4, wherein the electroplated layer disposed on the exposed top surfaces of the leads partially covers the top surfaces of the leads.

6. The package of claim 5, wherein the encapsulant further comprises a protrusion that extends onto portions of the top surfaces of the leads that are not covered with the electroplated layer.

7. The package of claim 4, further comprising an encapsulant formed on a top surface of the electroplated layer.

8. The package of claim 1, wherein the semiconductor chip is adhered to a top surface of the mounting portion using an adhesive, and
the encapsulant further comprises a protrusion formed on the top surface of the mounting portion around the semiconductor chip or an extended portion of the encapsulant extended toward the semiconductor chip inwardly around the semiconductor chip in order to prevent the adhesive from overflowing toward the leads.
formed around the semiconductor chip in order to prevent the adhesive from overflowing toward the leads.

9. The package of claim 1, wherein outer sidewalls of the leads are exposed.

10. The package of claim 1, further comprising a transparent plate adhered onto the leads over the semiconductor chip.

11. The package of claim 1, further comprising an opaque plate adhered onto the leads over the semiconductor chip.

12. A method of fabricating a semiconductor package, comprising:
preparing a lead frame including a plurality of units, each unit including a plurality of leads that protrude toward an inner space;
molding each of the units using an encapsulant to expose top and bottom surfaces of the leads and encapsulate sidewalls and a bottom of the semiconductor package;
adhering a semiconductor chip including a plurality of bonding pads onto the bottom of the semiconductor package between the leads;
wire-bonding the leads to the bonding pads of the semiconductor chip;
encapsulating the semiconductor chip; and
separating each of the units from the lead frame using a singulation process.

13. The method of claim 12, wherein the lead frame includes a lead frame pad, which is separated from the leads and disposed between the leads, and the semiconductor chip is adhered onto the lead frame pad.

14. The method of claim 12, after the molding of each of the units and before the adhering of the semiconductor chip, further comprising forming a electroplated layer on the exposed top surfaces of the leads.

15. The method of claim 12, wherein the forming of the electroplated layer comprises forming the electroplated layer only on portions of the top surfaces of the leads.

16. The method of claim 14, further comprising forming an encapsulant on the electroplated layer.

17. The method of claim 14, further comprising forming a electroplated layer on the exposed bottom surfaces of the leads during the forming of the electroplated layer on the exposed top surfaces of the leads.

18. The method of claim 12, further comprising:
adhering a transparent plate over the leads; and
forming a solder electroplated layer on the exposed bottom surfaces of the leads.

19. The method of claim 12, wherein the encapsulating of the semiconductor chip comprises adhering a transparent plate over the leads with a predetermined space apart from the semiconductor chip.

20. The method of claim 19, wherein the transparent plate is adhered over the leads in each of the units.

21. The method of claim 19, wherein the transparent plate is adhered over the leads throughout the entire lead frame and separated into portions corresponding to the respective units during the singulation process.

22. A semiconductor package module for an image sensor, the module comprising:
a printed circuit board;
a semiconductor package mounted on the printed circuit board; and
a lens holder disposed over the semiconductor package,
wherein the semiconductor package comprises:
a mounting portion on which a semiconductor chip is mounted, wherein the mounting portion supports the semiconductor chip;
a semiconductor chip including a plurality of bonding pads disposed along an edge thereof, the semiconductor chip adhered onto the mounting portion;
a plurality of leads spaced apart from a sidewall of the semiconductor chip and having a greater height than the semiconductor chip;
an encapsulant for fixing the mounting portion and the leads, encapsulating a bottom surface and a sidewall of the semiconductor package, and exposing top and bottom surfaces of the leads;
bonding wires for connecting the bonding pads of the semiconductor chip with the exposed top surfaces of the leads; and
a transparent plate adhered over the leads with a predetermined space apart from the semiconductor chip.

23. The module of claim 22, wherein the lens holder is adhered onto the top surfaces of the leads of the semiconductor package.

24. A semiconductor package comprising:
a semiconductor chip including a plurality of bonding pads;
a plurality of leads spaced apart from a sidewall of the semiconductor chip and having bottom surfaces that are substantially on the same plane with a bottom surface of the semiconductor chip;
a plurality of bonding wires for electrically connecting the bonding pads of the semiconductor chip with the leads; and
an encapsulant for fixing and encapsulating the semiconductor chip, the bonding wires, and the leads and exposing the bottom surface of the semiconductor chip and the bottom surfaces of the leads.

25. The package of claim 24, wherein the encapsulant is formed of one of a transparent material and an opaque material.

26. The package of claim 24, wherein the encapsulant is higher than top surfaces of the leads.

27. The package of claim 24, further comprising:
an upper electroplated layer disposed on exposed top surfaces of the leads; and
a lower electroplated layer disposed on the exposed bottom surfaces of the leads,
wherein the bonding wires are connected to the upper electroplated layer disposed on the top surfaces of the leads.

28. The package of claim 24, further comprising a semiconductor chip pad disposed on the bottom surface of the semiconductor chip,
wherein a bottom surface of the semiconductor chip pad is substantially on the same plane with the bottom surfaces of the leads.

29. The package of claim 24, further comprising at least a semiconductor package according to claim 24 stacked vertically on the semiconductor package of claim 24 using an adhesive.

30. A method of fabricating a semiconductor package, comprising:
preparing a lead frame including a plurality of leads that protrude toward an inner space;
adhering a tape onto a bottom surface of the lead frame;
adhering a semiconductor chip onto the tape exposed in the inner space of the lead frame;
electrically connecting the leads with the semiconductor chip using bonding wires;
encapsulating the leads, the bonding wires, and the semiconductor chip using an encapsulant; and
removing the tape from the semiconductor chip.

31. The method of claim 30, further comprising before the adhering of the tape onto the bottom surface of the lead frame, forming an upper electroplated layer on top surfaces of the leads and forming a lower electroplated layer on bottom surfaces of the leads.

32. The method of claim 30, wherein the encapsulating of the semiconductor chip comprises forming the encapsulant on a higher level than the leads.

33. The method of claim 30, wherein the encapsulant is formed of a transparent material.

34. A semiconductor package module for an image sensor, the module comprising:
a semiconductor package; and
a lens holder disposed over the semiconductor package,
wherein the semiconductor package comprises:
a semiconductor chip including a plurality of bonding pads;
a plurality of leads spaced apart from a sidewall of the semiconductor chip and having bottom surfaces that are substantially on the same plane with a bottom surface of the semiconductor chip;
a plurality of bonding wires for electrically connecting the bonding pads of the semiconductor chip with the leads; and
an encapsulant for fixing and encapsulating the semiconductor chip, the bonding wires, and the leads and exposing the bottom surface of the semiconductor chip and the bottom surfaces of the leads.

35. The module of claim 34, further comprising a PCB to which the semiconductor package is adhered,
wherein the PCB includes an opening having a greater dimension than the semiconductor chip of the semiconductor package, and the semiconductor package is adhered onto a bottom surface of the PCB.
